(19) United States
(12) Patent Application Publication
(10) Pub. No.: US 2026/0257909 A1
(43) Pub. Date: Sep. 3, 2026

(54) MICROMECHANICAL SENSOR DEVICE AND CORRESPONDING PRODUCTION METHOD

(71) Applicant: Robert Bosch GmbH, Stuttgart (DE)

(72) Inventors: David Slogsnat, Tuebingen (DE); Manuel Glas, Kirchentellinsfurt (DE); Pascal Gieschke, Reutlingen (DE)

(21) Appl. No.: 18/875,290

(22) PCT Filed: May 3, 2023
(86) PCT No.: PCT/EP2023/061688

§ 371 Date: Dec. 16, 2024

(30) Foreign Application Priority Data
Jun. 24, 2022 (DE) 10 2022 206 385.6

(51) Int. Cl. B81B 7/00; B81C 1/00

(52) U.S. Cl. CPC B81B 7/0061; B81C 1/00309; B81B 2201/0257; B81B 2201/0264; B81B 2203/0127; B81B 2203/0163; B81B 2203/0315; B81B 2207/015; B81B 2207/07; B81B 2207/096; B81C 2203/037

(57) ABSTRACT

A micromechanical sensor device and a corresponding production method. The micromechanical sensor device is equipped with a micromechanical sensor device including a MEMS sensor chip, which has a first upper side and a first underside, and an ASIC chip, which has a second upper side and a second underside, wherein an exposed cavity is formed on the first upper side. A sensor core of the MEMS sensor chip is elastically suspended inside the cavity via a spring device on the periphery of the cavity in the sensor chip. The ASIC chip is bonded with the second upper side to the first upper side of the MEMS sensor chip. A passage opening that opens into the cavity is provided on the first underside as a media access, wherein the sensor core includes at least one sensor region that is sensitive to a medium passed through the passage opening.

### FIELD

The present invention relates to a micromechanical sensor device and a corresponding production method.

### BACKGROUND INFORMATION

Although applicable to any micromechanical sensor devices, the present invention and its underlying problem are explained with reference to silicon-based micromechanical pressure sensor devices.

State-of-the-art barometric pressure sensors have media access from above (medium in a barometric sensor usually refers to ambient air, but other gaseous or liquid substances, such as water, the pressure of which is measured are possible as well).

The media access is located in the metal lid as an opening, for example. For media-robust variants of pressure sensors (i.e. the sensor element is protected via a membrane or via a silicone-based gel), media access is made from the upper side.

According to the related art, there is already also ASIC-MEMS wafer bonding and stress decoupling; in this design concept always with media access from above. For microphones, on the other hand, it has become common-place for media access to be through the underside of the sensor.

Germany Patent No. DE 10 2013 200 070 B3 describes a microphone component comprising a MEMS microphone component with at least one microphone structure configured in the front side of the component, an ASIC component comprising evaluation electronics for the microphone signal of the MEMS microphone component and a housing comprising a sound opening, wherein the MEMS microphone component is mounted within the housing and above the sound opening in such a way that the rear side of the microphone structure is acted on by the sound pressure, and wherein the ASIC component likewise comprises a MEMS microphone structure, the microphone signal of which is fed to the evaluation electronics.

Germany Patent No. DE 10 2014 214 532 B3 describes a design concept for components comprising a MEMS component, the micromechanical function of which requires a media connection to the surroundings, and comprising a cap structure for this micromechanical component. The cap structure closes at least one first cavity section above the micromechanical component and at least one second cavity section on the side of this micromechanical component so that the two cavity sections are connected to one another, wherein the connection region between the two cavity sections is designed as a particle filter. The media connection opening is disposed in the region of the second cavity section.

### SUMMARY

The present invention provides a micromechanical sensor device and a corresponding production method.

Preferred further developments of the present invention are disclosed herein.

The here-described present invention provides a sensor device with media access from the underside. An advantage of this is that the sensor can be integrated into smartphones, smartwatches and other devices using the same process that is used for the already existing microphones. This provides potential savings for the integration since the number of process steps there can be reduced. At the same time, the sensor device is configured such that it can be produced at lower cost than state-of-the-art media-robust sensors.

According to an example embodiment of the present invention, the MEMS chip in the cavity is stress-decoupled by the suspension of the spring, wherein the cavity is closed at the front by the ASIC chip and only has a first passage opening that opens into the cavity at the back as a media access.

According to a preferred further development of the present invention, the first underside is bonded to a substrate comprising a second passage opening that connects to the first passage opening. This enables media access through the substrate.

According to another preferred further development of the present invention, the MEMS sensor chip and the ASIC chip are embedded on the substrate in a molded package. This makes it possible to form an effective encapsulation for the chips.

According to another preferred further development of the present invention, at least one first bond pad is configured on the second underside, wherein at least one second bond pad is configured on the substrate, and wherein the first and second bond pad are electrically connected to one another via a bond connection. The sensor device can thus be easily connected to external circuit components.

According to another preferred further development of the present invention, first contact regions are configured on the first upper side and corresponding second contact regions are configured on the second upper side which are bonded to the first contact regions. This makes it possible to realize direct electrical connections between the chips.

According to another preferred further development of the present invention, the ASIC chip is bonded with the second upper side to the first upper side of the MEMS sensor chip via a peripheral bond frame. This makes it possible to create a hermetic closure of the cavity on the front side.

According to another preferred further development of the present invention, the at least one sensor region is a pressure-sensitive membrane region which is clamped in the sensor core. The entire pressure-sensitive membrane region is thus stress-decoupled.

According to another preferred further development of the present invention, the spring device comprises a spring which has an angled configuration. This makes it possible to achieve a particularly elastic soft coupling.

### BRIEF DESCRIPTION OF THE DRAWINGS

Further features and advantages of the present invention are explained in the following by means of example embodiments with reference to the figures.

FIG. 1A-1C show schematic views to illustrate a micromechanical sensor device and a corresponding production method according to an embodiment of the present invention, namely FIG. 1A in vertical cross-section, FIG. 1B in plan view onto the MEMS sensor chip and FIG. 1C in vertical cross-section through the MEMS sensor chip.

### DETAILED DESCRIPTION OF EXAMPLE EMBODIMENTS

Identical reference signs in the figures denote identical or functionally identical elements.

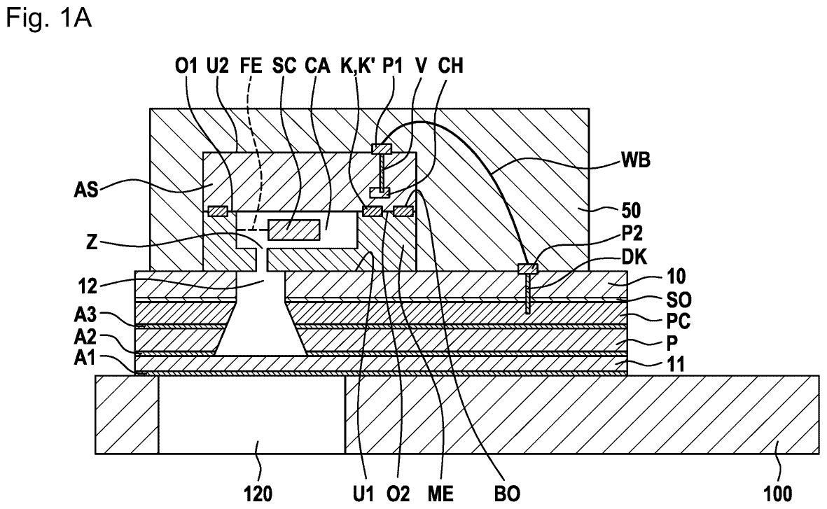

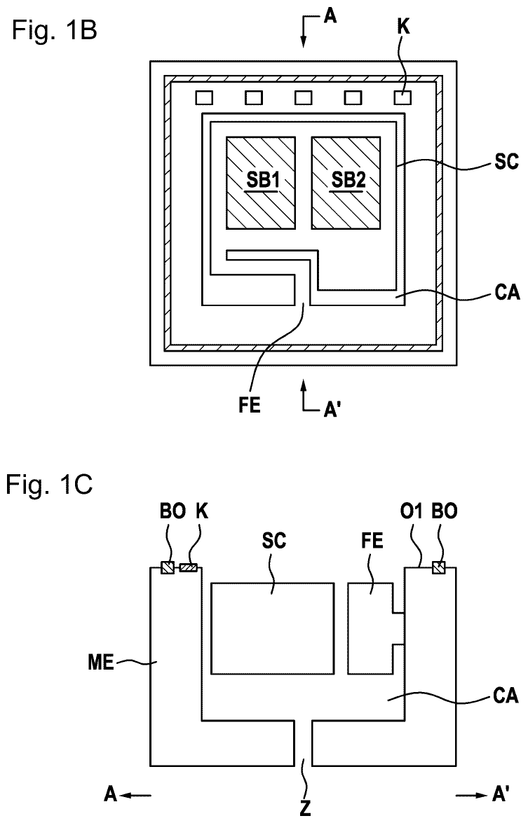

FIG. 1A-1C are schematic views to illustrate a micromechanical sensor device and a corresponding production method according to an embodiment of the present invention, namely FIG. 1A in vertical cross-section, FIG. 1B in plan view onto the MEMS sensor chip and FIG. 1C in vertical cross-section through the MEMS sensor chip.

FIG. 1A-1C show the micromechanical sensor device according to the embodiment of the present invention in an example mounting structure on a cell phone, specifically as a pressure sensor device.

The micromechanical sensor device comprises a MEMS sensor chip ME, which has a first upper side O1 and a first underside U1, and an ASIC chip AS, which has a second upper side O2 and a second underside U2. The ASIC chip 2 comprises a (not depicted) evaluation circuit for the MEMS sensor chip SE.

An exposed cavity CA is formed on the first upper side O1, wherein a sensor core SC of the MEMS sensor chip ME is elastically suspended inside the cavity CA in a stress-decoupled manner via a spring device FE with an angled spring on the periphery of the cavity CA in the sensor chip ME. A first passage opening Z that opens into the cavity CA is provided on the first underside U1 as a media access, in the present case for ambient air.

The sensor core SC comprises a first and a second sensor region SB1, SB2, which are pressure-sensitive to the ambient air passed through the passage opening Z, e.g. by means of (not depicted) piezoresistive or capacitive structures. A capacitive sensor structure consists, for instance, of a membrane stretched over a cavity, wherein the membrane forms an electrode of the capacitance, or the electrode is at least attached to the membrane and moves with it when the pressure changes. A second electrode of the capacitance is disposed inside or on the side of the cavity opposite to the membrane. The sensor core SC can comprise a plurality of such sensor elements. It is also possible for pressure-insensitive elements that serve as reference capacitances to be formed in the sensor core.

Other elements such as diodes and resistors for temperature measurement SC can be included in the sensor core.

The ASIC chip AS is bonded with the second upper side O2 to the first upper side O1 of the MEMS sensor chip ME via a peripheral bond frame BO, e. g. by eutectic bonding.

First contact regions K are configured on the first upper side O1 and corresponding second contact regions K′ are configured on the second upper side O2 which are bonded to the first contact regions K1.

The first underside U1 is bonded to a substrate 10, e.g. by means of an adhesive film, for example by means of a die attach film. The substrate 10, for example a ceramic substrate, comprises a second passage opening 12 that connects to the first passage opening Z.

The MEMS sensor chip ME and the ASIC chip AS are embedded on the substrate 10 in a molded package 50. A first bond pad P1 is configured on the second underside U2, and a second bond pad P2 is configured on the substrate 10, wherein the first and second bond pad P1, P2 are electrically connected to one another via a bond connection WB.

The first bond pad P1 is connected via an electrical via V to a circuit region CH of the ASIC chip AS which is disposed in the front region of said ASIC chip. The second bond pad P2 is likewise electrically connected to deeper circuit components by means of a via DK of the substrate 10.

Not shown are possible further first and second bond pads, which can form further electrical connections.

The thus far described structure forms a 1st level package, which is followed by a 2nd level package, the components of which are described below.

The substrate 10 is connected, for instance via a solder layer SO, to a printed circuit board PC, which carries said deeper circuit components that are not discussed in more detail here.

The further structure of the 2nd level package comprises a partially shown cell phone housing 100, a membrane layer 11, e.g. made of polytetrafluoroethylene or Teflon, and a sealing layer P, e. g. made of polyester, which are connected to one another via a first, second and third adhesive layer A1, A2, A3.

Except for the membrane layer 11, the layers A1, 11, A2, P, A3, PC and the circuit board PC are interrupted in the region of the passage opening 12. The cell phone housing 100 comprises an external access opening 120, which is separated from the rear side passage opening Z of the MEMS chip ME only by the membrane layer 11.

The present invention is particularly advantageously applicable to small and cost-efficient, highly sensitive and robust MEMS sensor devices, such as pressure sensors, microphones, loudspeakers, etc.

Even though the present invention has been described with reference to preferred embodiment examples, it is not limited to these. The mentioned materials and topologies are in particular solely examples and are not limited to the described examples.

1-15. (canceled)

16. A micromechanical sensor device, comprising:
a MEMS sensor chip, which has a first upper side and a first underside;
an ASIC chip, which has a second upper side and a second underside;
wherein an exposed cavity (CA) is formed on the first upper side,
wherein a sensor core of the MEMS sensor chip is elastically suspended inside the cavity via a spring device on a periphery of the cavity in the sensor chip,
wherein the ASIC chip is bonded with the second upper side to the first upper side of the MEMS sensor chip,
wherein a first passage opening that opens into the cavity is provided on the first underside as a media access, and
wherein the sensor core includes at least one sensor region that is sensitive to a medium passed through the passage opening.

17. The micromechanical sensor device according to claim 16, wherein the first underside is bonded to a substrate which includes a second passage opening that connects to the first passage opening.

18. The micromechanical sensor device according to claim 17, wherein the MEMS sensor chip and the ASIC chip are embedded on the substrate in a molded package.

19. The micromechanical sensor device according to claim 18, wherein at least one first bond pad is configured on the second underside, wherein at least one second bond pad is configured on the substrate, and wherein the first bond pad and the second bond pad are electrically connected to one another via a bond connection.

20. The micromechanical sensor device according to claim 16, wherein first contact regions are configured on the first upper side and corresponding second contact regions are configured on the second upper side which are bonded to the first contact regions.

21. The micromechanical sensor device according to claim 16, wherein the ASIC chip is bonded with the second upper side to the first upper side of the MEMS sensor chip via a peripheral bond frame.

22. The micromechanical sensor device according to claim 16, wherein the at least one sensor region is a pressure-sensitive membrane region including a capacitive pressure-sensitive membrane region, which is clamped in the sensor core.

23. The micromechanical sensor device according to claim 16, wherein the spring device includes a spring which has an angled configuration.

24. A production method for a micromechanical sensor device, comprising the following steps:
providing a MEMS sensor chip, which has a first upper side and a first underside, and an ASIC chip, which has a second upper side and a second underside,
wherein an exposed cavity is formed on the first upper side;
wherein a sensor core of the MEMS sensor chip is elastically suspended inside the cavity via a spring device on the periphery of the cavity in the sensor chip,
wherein a first passage opening that opens into the cavity is provided on the first underside as a media access, and
wherein the sensor core includes at least one sensor region that is sensitive to a medium passed through the passage opening; and
bonding the ASIC chip with the second upper side to the first upper side of the MEMS sensor chip.

25. The production method according to claim 24, wherein the first underside is bonded to a substrate which includes a second passage opening that connects to the first passage opening.

26. The production method according to claim 25, wherein the MEMS sensor chip and the ASIC chip are embedded on the substrate in a molded package.

27. The production method according to claim 26, wherein a first bond pad is configured on the second underside, wherein a second bond pad is configured on the substrate, and wherein the first bond pad and the second bond pad re electrically connected to one another via a bond connection.

28. The production method according to claim 24, wherein first contact regions are configured on the first upper side and corresponding second contact regions are configured on the second upper side which are bonded to the first contact regions.

29. The production method according to claim 24, wherein the ASIC chip is bonded with the second upper side to the first upper side of the MEMS sensor chip via a peripheral bond frame.

30. The production method according to claim 29, wherein the bonding is a eutectic bonding, and is carried out at wafer level.
